(19) United States
(12) Patent Application Publication
(10) Pub. No.: US 2025/0357201 A1
(43) Pub. Date: Nov. 20, 2025

(54) SEMICONDUCTOR STRUCTURE AND MANUFACTURING METHOD THEREOF

(71) Applicant: Winbond Electronics Corp., Taichung City (TW)

(72) Inventors: Po-Chun Shao, Hsinchu (TW); Ping-Lung Yu, Hsinchu (TW)

(73) Assignee: Winbond Electronics Corp., Taichung City (TW)

(21) Appl. No.: 19/048,975

(22) Filed: Feb. 10, 2025

(30) Foreign Application Priority Data
May 20, 2024 (TW) 113118645

(51) Int. Cl. H01L 21/768; H01L 23/48

(52) U.S. Cl. CPC H01L 21/76859; H01L 21/76846; H01L 21/76856; H01L 21/76898; H01L 23/481; H01L 21/76831

(57) ABSTRACT

A semiconductor structure includes a substrate, a dielectric liner layer, a through-substrate via (TSV), a barrier layer, a copper germanium layer, and a copper layer. The substrate includes a first side and a second side opposite to each other. A hole is disposed in the substrate. The dielectric liner layer is located on a sidewall of the hole. The TSV is located in the hole. The dielectric liner layer is located between the TSV and the substrate. The barrier layer is located between the TSV and the dielectric liner layer. The copper germanium layer is located between the TSV and the barrier layer. The copper germanium layer is adjacent to the first side and adjacent to the corner of the hole. The copper layer is located between the TSV and the barrier layer. The copper layer is connected to the copper germanium layer and adjacent to the second side.

### CROSS-REFERENCE TO RELATED APPLICATION

This application claims the priority benefit of Taiwan application no. 113118645, filed on May 20, 2024. The entirety of the above-mentioned patent application is hereby incorporated by reference herein and made a part of this specification.

### BACKGROUND

### Technical Field

The present disclosure relates to a semiconductor structure and a manufacturing method thereof, and in particular, to a semiconductor structure including a through-substrate via (TSV) and a manufacturing method thereof.

### Description of Related Art

In a TSV manufacturing process, holes are first formed in a substrate, and then a dielectric liner layer, a barrier layer and a TSV are formed in the holes. The dielectric liner layer is located between the TSV and the substrate. The barrier layer is located between the TSV and the dielectric liner layer. Since the depth of the hole for accommodating the TSV is relatively deep, in order to increase the thickness of the barrier layer located at the bottom of the hole, an AC power will be increased to increase the hole-filling ability of the barrier layer. As a result, the thickness of the barrier layer formed at the top corner of the hole is thin, and the ingredients of the TSV are very likely to diffuse through the barrier layer at the top corner of the hole, which causes contamination.

### SUMMARY

The present disclosure provides a semiconductor structure and a manufacturing method thereof, which may prevent contamination caused by the diffusion of ingredients of a through-substrate via (TSV).

The present disclosure provides a semiconductor structure including a substrate, a dielectric liner layer, a through-substrate via (TSV), a barrier layer, a copper germanium (Cu₃Ge) layer, and a copper layer. The substrate includes a first side and a second side opposite to each other. A hole is disposed in the substrate. The dielectric liner layer is located on a sidewall of the hole. The TSV is located in the hole. The dielectric liner layer is located between the TSV and the substrate. The barrier layer is located between the TSV and the dielectric liner layer. The copper germanium layer is located between the TSV and the barrier layer. The copper germanium layer is adjacent to the first side and adjacent to the corner of the hole. The copper layer is located between the TSV and the barrier layer. The copper layer is connected to the copper germanium layer and adjacent to the second side.

The present disclosure provides a method for manufacturing a semiconductor structure, which may include the following steps: providing a substrate, the substrate includes a first side and a second side that are opposite to each other; forming a hole in the substrate; forming a dielectric liner layer on the sidewall of the hole; forming a TSV in the hole, the dielectric liner layer is located between the TSV and the substrate; forming a barrier layer between the TSV and the dielectric liner layer; forming a copper germanium layer between the TSV and the barrier layer, the copper germanium layer is adjacent to the first side and adjacent to the corner of the hole; forming the first copper layer between the TSV and the barrier layer, the first copper layer is connected to the copper germanium layer and adjacent to the second side.

In order to make the above-mentioned features and advantages of the present disclosure comprehensible to understand, embodiments are given below and are described in detail below with reference to the accompanying drawings.

### BRIEF DESCRIPTION OF THE DRAWINGS

FIG. 1A to FIG. 1J are cross-sectional views of a manufacturing process of a semiconductor structure according to some embodiments of the present disclosure.

### DESCRIPTION OF THE EMBODIMENTS

The following embodiments are enumerated and described in detail with reference to the accompanying drawings, but the provided embodiments are not intended to limit the scope of the present disclosure. To facilitate understanding, the same components will be identified with the same symbols in the following description. In addition, the drawings are for illustrative purposes only and are not drawn to original size. In fact, the dimensions of the various features may be increased or reduced freely for clarity of discussion.

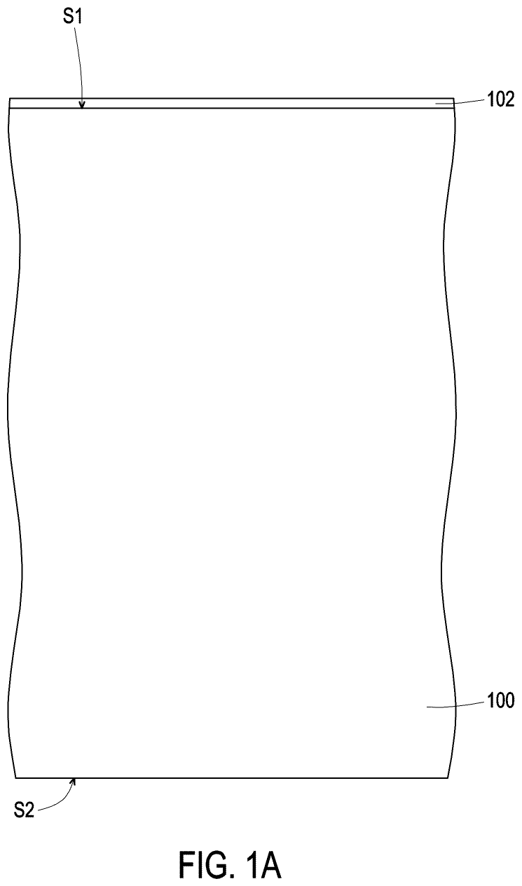

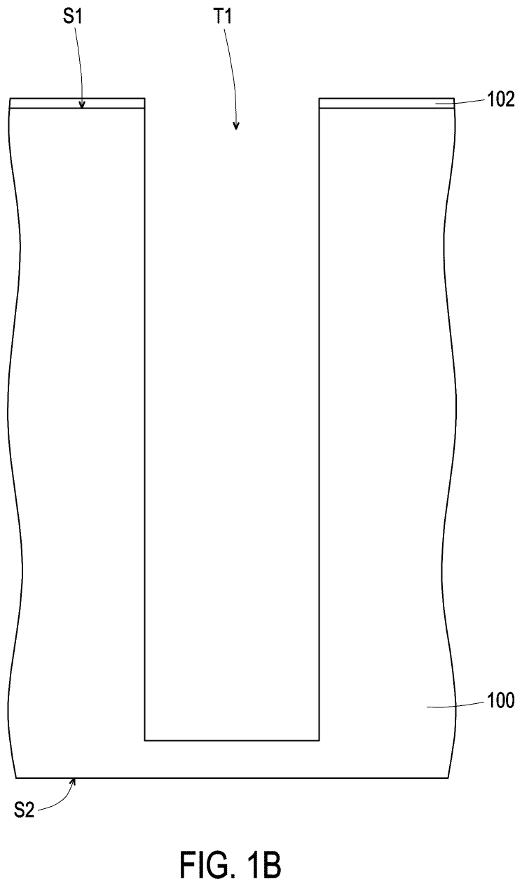

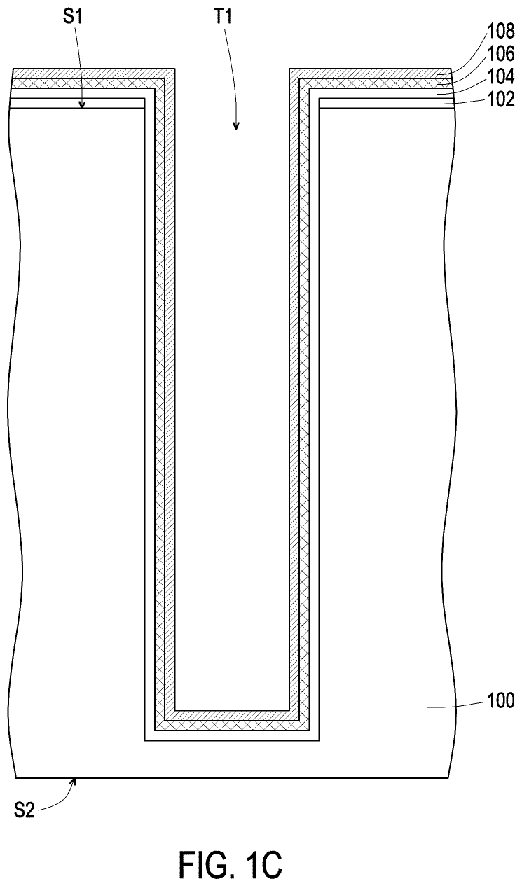

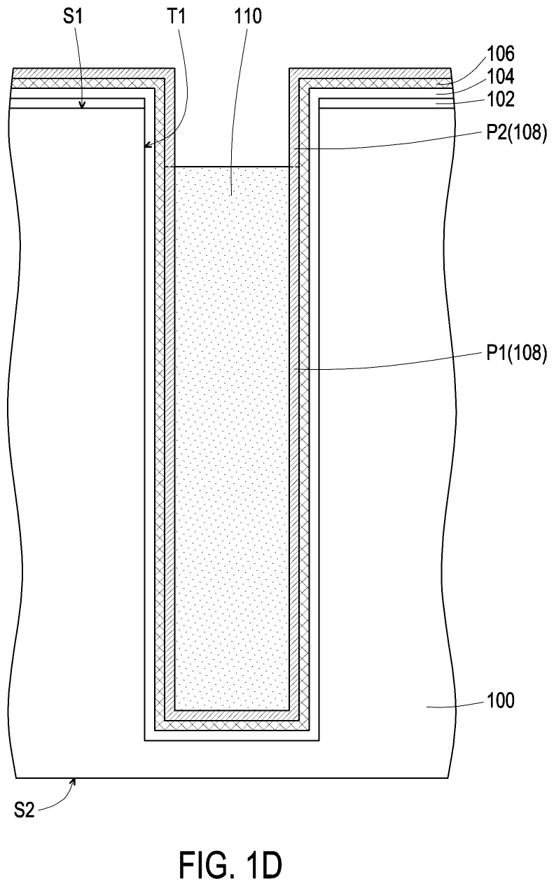

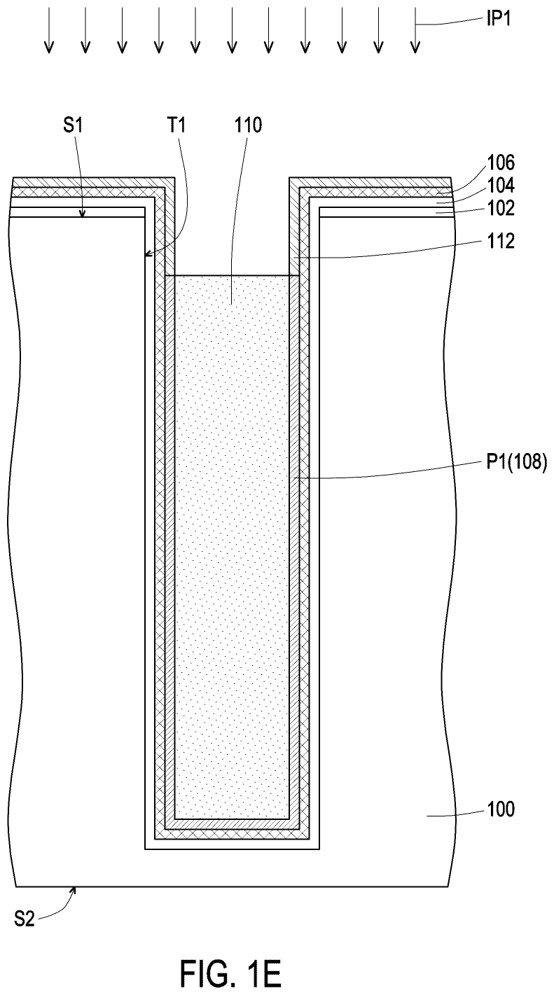

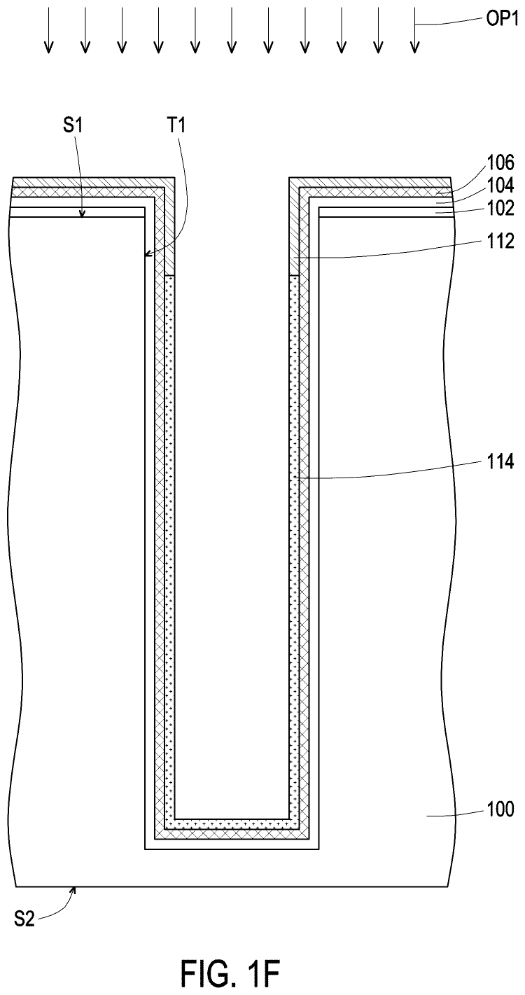

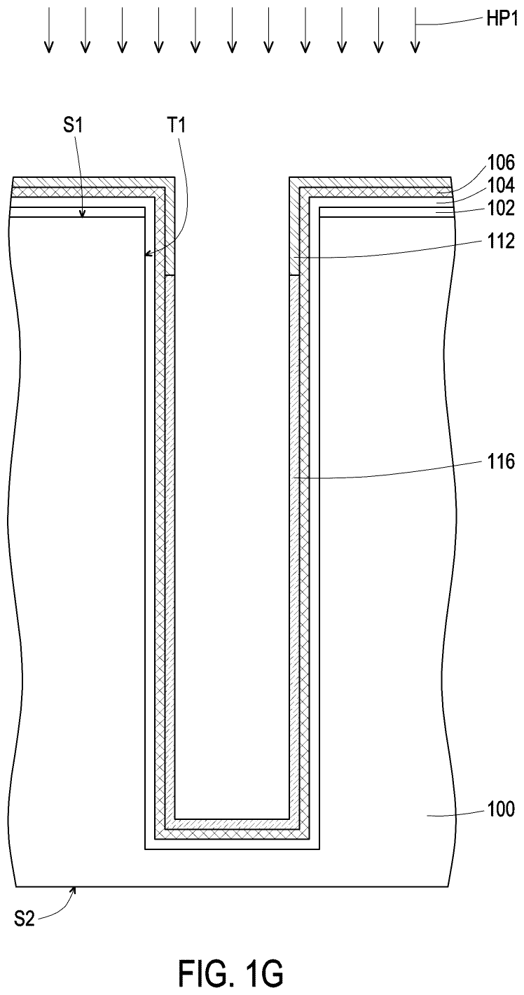

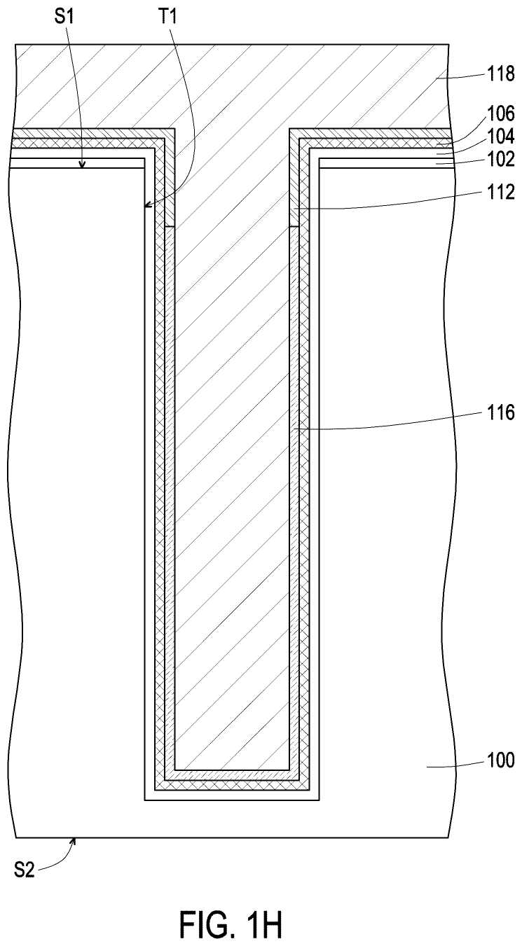

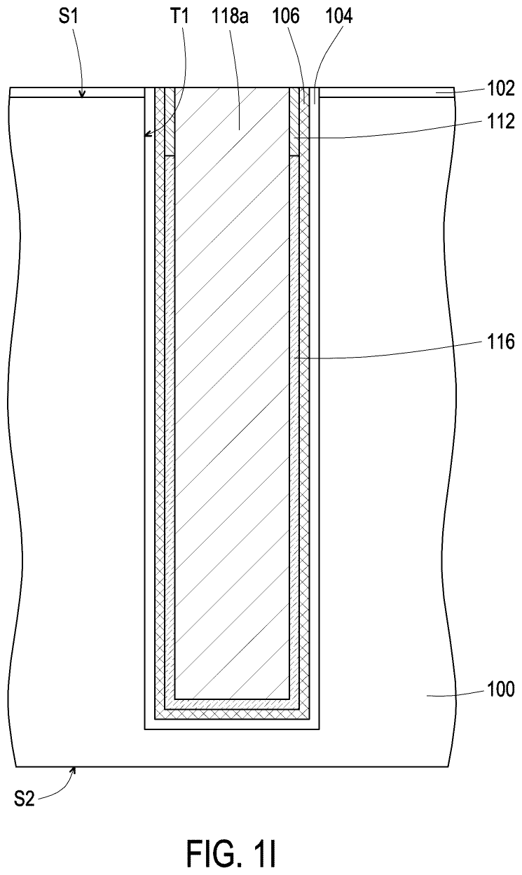

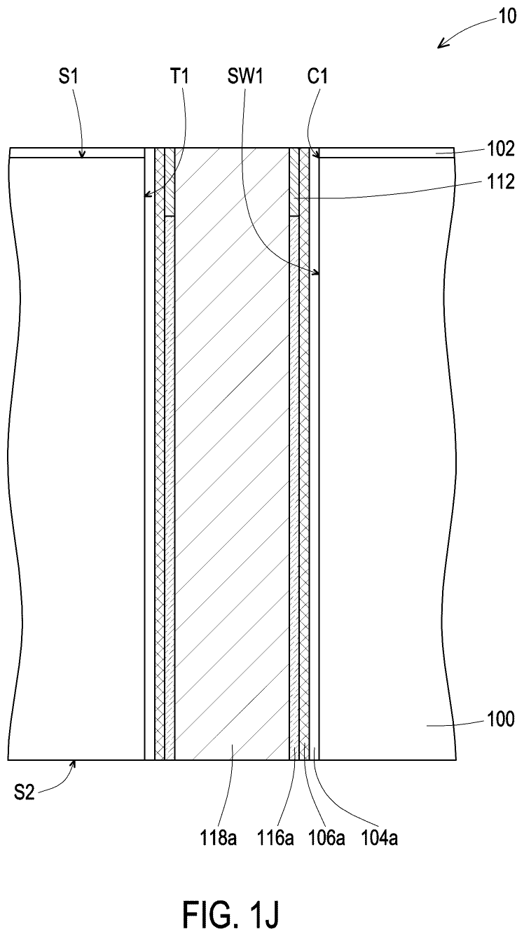

FIG. 1A to FIG. 1J are cross-sectional views of a manufacturing process of a semiconductor structure according to some embodiments of the present disclosure.

Referring to FIG. 1A, a substrate 100 is provided. The substrate 100 includes a first side S1 and a second side S2 opposite to each other. In an embodiment, the first side S1 may be the front side of the substrate 100, and the second side S2 may be the back side of the substrate 100. In an embodiment, the substrate 100 may be a semiconductor substrate, such as silicon substrate. In addition, although not shown in the FIGURE, required components (such as semiconductor devices, dielectric layers and/or interconnect structures) may be provided on and/or in the substrate 100, and related description is omitted here.

Next, a dielectric layer 102 may be formed on the first side S1. In an embodiment, the material of the dielectric layer 102 is, for example, silicon nitride. In an embodiment, the dielectric layer 102 is formed by a chemical vapor deposition method, for example.

Referring to FIG. 1B, the hole T1 is formed in substrate 100. The hole T1 may pass through the dielectric layer 102. In an embodiment, the hole T1 may be a deep hole. In an embodiment, the hole T1 may be formed by patterning the dielectric layer 102 and the substrate 100 through a photolithography process and an etching process.

Referring to FIG. 1C, a dielectric liner material layer 104 may be conformally formed in the hole T1. In an embodiment, the dielectric liner material layer 104 may be further formed on the dielectric layer 102. In an embodiment, the material of the dielectric liner material layer 104 is, for example, silicon oxide. In an embodiment, the method of forming the dielectric liner material layer 104 includes an atomic layer deposition method.

Next, a barrier material layer 106 may be conformally formed on the dielectric liner material layer 104. The barrier material layer 106 may be a single-layer structure or a multi-layer structure. In an embodiment, the material of the barrier material layer 106 is, for example, tantalum (Ta), tantalum nitride (TaN), or a combination thereof. In an embodiment, the barrier material layer 106 is formed by, for example, a physical vapor deposition method or a chemical vapor deposition method.

Then, a copper material layer 108 may be conformally formed in the hole T1. In an embodiment, the copper material layer 108 may be conformally formed on the barrier material layer 106. In an embodiment, the material of the copper material layer 108 is, for example, copper. In an embodiment, the copper material layer 108 is formed by, for example, a physical vapor deposition method or a chemical vapor deposition method.

Referring to FIG. 1D, a filling layer 110 may be formed in the hole T1. The filling layer 110 may cover the first portion P1 of the copper material layer 108 located in the hole T1 and expose the second portion P2 of the copper material layer 108 located in the hole T1. The second portion P2 of the copper material layer 108 may be located above the first portion P1 of the copper material layer 108. In an embodiment, the material of the filling layer 110 is, for example, spin-on-carbon (SOC). In an embodiment, the filling layer 110 is formed by a spin coating method, for example.

Referring to FIG. 1E, an ion implantation process IP1 may be performed on the second portion P2 of the copper material layer 108 to form the copper germanium layer 112. The copper germanium layer 112 may serve as a barrier layer. In an embodiment, the content of germanium in the copper germanium layer 112 may range from 0.1 atomic percent (at. %) to 50 at. %. In an embodiment, the content of germanium in the copper germanium layer 112 may range from 15 at. % to 35 at. %. In an embodiment, the dopant used in the ion implantation process IP1 may include germanium.

Referring to FIG. 1F, the filling layer 110 may be removed using the oxygen plasma process OP1. The first portion P1 of the copper material layer 108 is oxidized into an oxidized copper layer (CuO₂) 114 in the oxygen plasma process OP1.

Referring to FIG. 1G, hydrogen plasma treatment HP1 may be used to reduce the oxidized copper layer 114 to form the copper material layer 116. The copper material layer 116 may serve as a seed layer. In addition, the hydrogen plasma treatment HP1 may be used to remove the residue left by the oxygen plasma process OP1. In an embodiment, the material of the copper material layer 116 is, for example, copper.

Referring to FIG. 1H, a TSV material layer 118 may be formed on the substrate 100. The TSV material layer 118 may be filled in the hole T1. In an embodiment, the material of the TSV material layer 118 may include copper. In an embodiment, the TSV material layer 118 is formed by, for example, an electrochemical plating (ECP) method.

Referring to FIG. 1I, the TSV material layer 118 located outside the hole T1 may be removed to form a TSV 118a. Thereby, the TSV 118a filled in the hole T1 may be formed. The TSV 118a is located on the copper material layer 116 and the copper germanium layer 112. In an embodiment, the material of the TSV 118a is, for example, copper. In an embodiment, the method of removing the TSV material layer 118 located outside the hole T1 is, for example, a chemical mechanical polishing method. For example, the dielectric layer 102 may serve as a polishing stop layer to remove part of the TSV material layer 118, part of the copper germanium layer 112, part of the barrier material layer 106, and part of the dielectric liner material layer 104 to form the TSV 118a.

Referring to FIG. 1J, a thinning process may be performed on the second side S2 of the substrate 100 to remove part of the substrate 100, part of the dielectric liner material layer 104, part of the barrier material layer 106 and part of the copper material layer 116 to form a dielectric liner layer 104a, a barrier layer 106a and a copper layer 116a, and expose the TSV 118a. Thereby, the dielectric liner layer 104a may be formed on a sidewall SW1 of the hole T1, the TSV 118a may be formed in the hole T1, the barrier layer 106a may be formed between the TSV 118a and the dielectric liner layer 104a, the copper germanium layer 112 may be formed between the TSV 118a and the barrier layer 106a, and the copper layer 116a may be formed between the TSV 118a and the barrier layer 106a. The hole T1 may pass through the substrate 100. The TSV 118a may pass through the substrate 100. In an embodiment, the material of the dielectric liner layer 104a is, for example, silicon oxide. In an embodiment, the material of the barrier layer 106a is, for example, tantalum, tantalum nitride or a combination thereof.

Hereinafter, the semiconductor structure 10 in the above embodiment will be described with reference to FIG. 1J. In addition, although the method for forming the semiconductor structure 10 is described by taking the above method as an example, the present disclosure is not limited thereto.

Referring to FIG. 1J, the semiconductor structure 10 includes the substrate 100, the dielectric liner layer 104a, the TSV 118a, the barrier layer 106a, the copper germanium layer 112 and the copper layer 116a. The substrate 100 includes the first side S1 and the second side S2 opposite to each other. The hole T1 is disposed in the substrate 100. The dielectric liner layer 104a is located on the sidewall SW1 of the hole T1. The TSV 118a is located in the hole T1. The dielectric liner layer 104a is located between the TSV 118a and the substrate 100. The barrier layer 106a is located between the TSV 118a and the dielectric liner layer 104a. The copper germanium layer 112 is located between the TSV 118a and the barrier layer 106a. The copper germanium layer 112 is adjacent to the first side S1 and adjacent to the corner C1 of the hole T1. The copper layer 116a is located between the TSV 118a and the barrier layer 106a. The copper layer 116a is connected to the copper germanium layer 112 and adjacent to the second side S2. In an embodiment, the semiconductor structure 10 may further include the dielectric layer 102. The dielectric layer 102 is located on the first side S1. The hole T1 may pass through the dielectric layer 102.

In addition, the details of each component in the semiconductor structure 10 (such as materials and forming methods, etc.) have been described in detail in the above embodiments and will not be described again.

Based on the above embodiments, it can be seen that in the semiconductor structure 10 and the manufacturing method thereof, the copper germanium layer 112 is located between the TSV 118a and the barrier layer 106a, and the copper germanium layer 112 is adjacent to the first side S1 and adjacent to the corner C1 of the hole T1. Since the copper germanium layer 112 may block the diffusion of ingredients of the TSV 118a, even if the barrier layer 106a adjacent to the top corner (e.g., corner C1) of the hole T1 is thinned, it is possible to avoid contamination caused by the diffusion of ingredients of the TSV 118a.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the scope to be protected by the present disclosure shall be determined by the appended claims.

What is claimed is:

1. A semiconductor structure, comprising:
a substrate, comprising a first side and a second side opposite to each other, wherein a hole is disposed in the substrate;
a dielectric liner layer, located on a sidewall of the hole;
a through-substrate via (TSV), located in the hole, wherein the dielectric liner layer is located between the TSV and the substrate;
a barrier layer, located between the TSV and the dielectric liner layer;
a copper germanium layer, located between the TSV and the barrier layer, wherein the copper germanium layer is adjacent to the first side and adjacent to a corner of the hole; and
a copper layer, located between the TSV and the barrier layer, wherein the copper layer is connected to the copper germanium layer and adjacent to the second side.

2. The semiconductor structure according to claim 1, wherein a content of germanium in the copper germanium layer ranges from 0.1 atomic percent (at. %) to 50 at. %.

3. The semiconductor structure according to claim 1, wherein a content of germanium in the copper germanium layer ranges from 15 at. % to 35 at. %.

4. The semiconductor structure according to claim 1, wherein the hole passes through the substrate.

5. The semiconductor structure according to claim 1, wherein a material of the dielectric liner layer comprises silicon oxide.

6. The semiconductor structure according to claim 1, wherein the TSV passes through the substrate.

7. The semiconductor structure according to claim 1, wherein a material of the TSV comprises copper.

8. The semiconductor structure according to claim 1, wherein a material of the barrier layer comprises tantalum, tantalum nitride or a combination thereof.

9. The semiconductor structure according to claim 1, further comprising:
a dielectric layer, located on the first side, wherein the hole passes through the dielectric layer.

10. The semiconductor structure according to claim 9, wherein a material of the dielectric layer comprises silicon nitride.

11. A method for manufacturing a semiconductor structure, comprising:
providing a substrate, wherein the substrate comprises a first side and a second side that are opposite to each other;
forming a hole in the substrate;
forming a dielectric liner layer on a sidewall of the hole;
forming a TSV in the hole, wherein the dielectric liner layer is located between the TSV and the substrate;
forming a barrier layer between the TSV and the dielectric liner layer;
forming a copper germanium layer between the TSV and the barrier layer, wherein the copper germanium layer is adjacent to the first side and adjacent to a corner of the hole; and
forming a first copper layer between the TSV and the barrier layer, wherein the first copper layer is connected to the copper germanium layer and adjacent to the second side.

12. The method for manufacturing the semiconductor structure according to claim 11, wherein the method of forming the copper germanium layer and the first copper layer comprises:
forming a first copper material layer conformally in the hole;
forming a filling layer in the hole, wherein the filling layer covers a first portion of the first copper material layer and exposes a second portion of the first copper material layer;
performing an ion implantation process on the second portion of the first copper material layer to form the copper germanium layer;
removing the filling layer using an oxygen plasma process, wherein the first portion of the first copper material layer is oxidized into an oxidized copper layer in the oxygen plasma process;
reducing the oxidized copper layer using a hydrogen plasma treatment to form a second copper material layer;
forming the TSV that is filled in the hole, wherein the TSV is located on the second copper material layer and the copper germanium layer; and
performing a thinning process on the second side of the substrate to remove a part of the substrate and a part of the second copper material layer to form the first copper layer and expose the TSV.

13. The method for manufacturing the semiconductor structure according to claim 12, wherein the method of forming the first copper material layer comprises a physical vapor deposition method or a chemical vapor deposition method.

14. The method for manufacturing the semiconductor structure according to claim 12, wherein a material of the filling layer comprises spin-on-carbon (SOC).

15. The method for manufacturing the semiconductor structure according to claim 12, wherein a dopant used in the ion implantation process comprise germanium.

16. The method for manufacturing the semiconductor structure according to claim 11, wherein the method of forming the dielectric liner layer and the barrier layer comprises:
forming a dielectric liner material layer conformally in the hole;
forming a barrier material layer conformally on the dielectric liner material layer; and
performing a thinning process on the second side of the substrate to remove a part of the substrate, a part of the dielectric liner material layer and a part of the barrier material layer to form the dielectric liner layer and the barrier layer.

17. The method for manufacturing the semiconductor structure according to claim 16, wherein the method of forming the barrier material layer comprises a physical vapor deposition method or a chemical vapor deposition method.

18. The method for manufacturing the semiconductor structure according to claim 11, wherein the method of forming the TSV comprises:
forming a TSV material layer on the substrate, wherein the TSV material layer is filled in the hole; and
removing the TSV material layer located outside the hole to form the TSV.

19. The method for manufacturing the semiconductor structure according to claim 18, wherein the method of removing the TSV material layer located outside the hole comprises a chemical mechanical polishing method.

20. The method for manufacturing the semiconductor structure according to claim 11, further comprising:
forming a dielectric layer on the first side, wherein the hole passes through the dielectric layer.
